(19) United States
(12) Patent Application Publication
(10) Pub. No.: US 2011/0164451 A1
(43) Pub. Date: Jul. 7, 2011

(54) SEMICONDUCTOR INTEGRATED CIRCUIT INCLUDING PROGRAMMABLE FUSE

(75) Inventors: Hong Gyeom KIM, Ichon-shi (KR); Eun Mi YEON, Ichon-shi (KR)

(73) Assignee: Hynix Semiconductor Inc., Ichon-shi (KR)

(21) Appl. No.: 12/836,461

(22) Filed: Jul. 14, 2010

(30) Foreign Application Priority Data
Jan. 5, 2010 (KR) 10-2010-0000431

(51) Int. Cl. G11C 16/04; G11C 17/16

(52) U.S. Cl. 365/185.17; 365/225.7

(57) ABSTRACT

A semiconductor integrated circuit comprises a plurality of fuses arranged to be spaced apart from one another by predetermined intervals, and a page buffer electrically connected to the plurality of fuses and configured to determine whether to disconnect the fuses. The fuses comprise a NAND flash string. The NAND flash string comprises a drain select transistor connected to a bit line, a flash memory cell electrically connected to the drain select transistor, and a source select transistor connected between the flash memory cell and a ground terminal.

### CROSS-REFERENCE TO RELATED APPLICATION

The present application claims priority under 35 U.S.C. §119(a) to Korean Application No. 10-2010-0000431, filed on Jan. 5, 2010, in the Korean Intellectual Property Office, which is incorporated herein by reference in its entirety as if set forth in full.

### BACKGROUND

1. Technical Field

Various embodiments of the present discloser generally relate to a semiconductor integrated circuit, and more particularly, to a semiconductor integrated circuit including programmable fuses.

2. Related Art

As the respective components constituting a semiconductor integrated circuit become smaller, and a greater number of components are integrated into a single semiconductor chip, the degree of defect density also increases. The increase in the defect density degrades the yield of semiconductor apparatuses. In serious cases, wafers on which semiconductor apparatuses are formed must be discarded.

In order to reduce defect density, redundancy circuits have been proposed to replace defective cells with redundancy cells. In the case of a semiconductor memory apparatus, redundancy circuits may be disposed in row lines (e.g., word lines) and column lines (e.g., bit lines), and each of the redundancy circuits comprises a fuse set group to store defective cell address information. The fuse set group comprises a fuse set array with a plurality of fuse lines. The fuse set may be programmed by selective laser cutting of the fuse lines.

However, conventional fuses which are cut by laser must be spaced by more than a laser alignment tolerance so they are not affected by a blowing of adjacent fuses. Therefore, it is difficult to reduce an area of a fuse box in proportion to the integration density of a semiconductor memory apparatus.

Furthermore, a conventional fuse employing the laser repair method is inconvenient because it may not be applied after a package.

### SUMMARY

In one aspect of the present invention, a semiconductor integrated circuit comprises: a plurality of fuses arranged to be spaced apart from one another by predetermined intervals; and a page buffer electrically connected to the plurality of fuses and configured to determine whether to disconnect the fuses, wherein the fuses comprise a NAND flash string. The NAND flash string may comprise: a drain select transistor connected to a bit line; a flash memory cell electrically connected to the drain select transistor; and a source select transistor connected between the flash memory cell and a ground terminal.

The fuses may be spaced apart by a minimum interval that may be provided by a lithography process.

In another aspect of the present invention, a semiconductor integrated circuit comprises: a plurality of fuses each comprising a flash memory element that is programmed to be cut off by a first voltage; and a page buffer electrically connected to the plurality of fuses and configured to determine the cut-off fuses.

The first voltage may be higher than a pumping voltage and lower than a programming voltage of the flash memory element.

The fuses and the page buffer may be electrically connected by a bit line.

### BRIEF DESCRIPTION OF THE DRAWINGS

The accompanying drawings, which are incorporated in and constitute a part of this specification, illustrate various embodiments consistent with the invention and, together with the description, serve to explain the principles of the invention.

FIG. 1 is a schematic diagram illustrating a fuse array of a semiconductor integrated circuit according to one embodiment of the invention.

FIG. 2 is a detailed circuit diagram illustrating a fuse of FIG. 1.

### DETAILED DESCRIPTION

Hereinafter, a semiconductor integrated circuit including a programmable fuse according to the present invention will be described below with reference to the accompanying drawings through preferred embodiments.

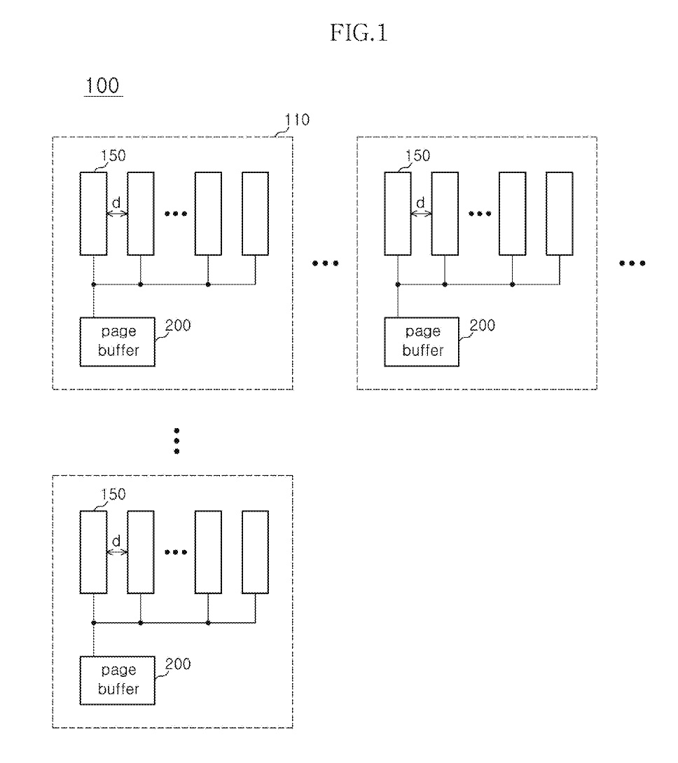

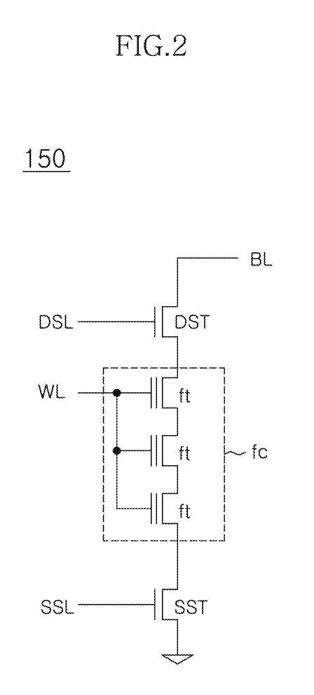

FIG. 1 is a schematic diagram illustrating a fuse array of a semiconductor integrated circuit according to one embodiment of the invention, and FIG. 2 is a detailed circuit diagram illustrating a fuse of FIG. 1.

Referring to FIG. 1, a fuse array 100 comprises a plurality of fuse blocks 110. The plurality of fuse blocks 110 may be arranged in matrix forms.

The respective fuse blocks 110 may have the same configuration and include a plurality of fuses 150 and a page buffer 200. The respective fuses 150 may be spaced apart by a minimum interval ‘d’ i.e., minimum feature size, which may be provided by a lithography process, regardless of a laser alignment tolerance.

As illustrated in FIG. 2, each fuse 150 may comprise a single NAND flash string structure.

Each fuse 150 may include a drain select transistor DST, a source select transistor SST, and a memory cell fc connected between the drain select transistor DST and the source select transistor SST.

The flash memory cell fc comprises a plurality of flash memory elements ft connected in series, or in a NAND structure. The flash memory cell fc may be implemented with a single flash memory element, or may be implemented by connecting a plurality of flash memory elements in series in order to increase their cut-off probability.

The drain select transistor DST may be configured to transfer a signal of a bit line BL to the flash memory cell fc in response to a signal from a drain select line DSL.

Control gates from a plurality of flash memory elements ft connected in series that constitute the flash memory cell fc may be commonly connected to a word line WL.

In response to a signal of a source select line SSL, the source select transistor SST may be configured to discharge a voltage from the flash memory cell fc to the ground.

According to this embodiment, the fuse 150 may be programmed with the following characteristics.

When the drain select transistor DST and the source select transistor SST are turned on, a high voltage is applied to the control gates of the flash memory elements ft through the word line WL. At this time, the high voltage may be in a programming voltage range of the flash memory apparatus. On the other hand, in other types of memory apparatuses, the high voltage may be lower than the programming voltage and higher than a pumping voltage (VPP).

In this case, floating gates of the flash memory elements ft are negatively charged by the high voltage applied through the word line WL. Therefore, the threshold voltages of the flash memory elements ft may increase.

Accordingly, while a current continuously flows before the programming (for example, before the voltage is applied to the word line WL), the current flow is interrupted after the programming (for example, after the voltage is applied to the word line WL). Consequently, a cut-off state (for example, a fuse cutting) may be achieved.

Meanwhile, the respective fuses 150 may be connected to the corresponding page buffers 200 through their bit lines BL.

The page buffer 200 is shared by the plurality of fuses 150 that constitute single fuse block 110. The page buffer 200 is configured to perform sensing and amplifying operations, for example, to operate as a latch when programming and reading the fuses 150. According to one embodiment, the page buffer 200 may be configured to have a conventional NAND flash page buffer structure.

The page buffer 200 programs the flash memory cell fc in the above-described manner when driving the redundancy circuit. The redundancy circuit may repair a failure of the memory apparatus, is receive address, read data of the flash memory cell fc in a read or write operation of the memory apparatus, and access a redundancy cell (not shown) when the addresses coincide with each other.

According to this embodiment, the fuses comprise the flash memory cell string. Since the fuses are configured with the flash memory cells, the fuses need not be spaced by more than the laser alignment tolerance. Since the flash memory cell string may be implemented in a very compact size, the area of the fuses themselves may also be reduced.

Moreover, since the fuses comprising the flash memory cells may be programmed by applying the voltage to the word line, they may perform the repair operation even after the package.

While certain embodiments have been described above, it will be understood to those skilled in the art that the embodiments described are by way of example only. Accordingly, the semiconductor integrated circuit described herein should not be limited to the described embodiments. Rather, the semiconductor integrated circuit described herein should only be limited in light of the claims that follow when taken in conjunction with the above description and accompanying drawings.

What is claimed is:

1. A semiconductor integrated circuit comprising:
a plurality of fuses arranged to be spaced from one another by predetermined intervals; and
a page buffer electrically connected to the plurality of fuses and configured to determine whether to disconnect the fuses,
wherein the fuses comprise a NAND flash string.

2. The semiconductor integrated circuit according to claim 1, wherein the NAND flash string comprises:
a drain select transistor connected to a bit line;
a flash memory cell electrically connected to the drain select transistor; and
is a source select transistor connected between the flash memory cell and a ground terminal.

3. The semiconductor integrated circuit according to claim 2, wherein the flash memory cell comprises a plurality of flash memory elements connected in series.

4. The semiconductor integrated circuit according to claim 3, wherein the plurality of flash memory elements are programmed by a high voltage applied through a word line.

5. The semiconductor integrated circuit according to claim 4, wherein the high voltage is higher than a pumping voltage and lower than a programming voltage of the flash memory elements.

6. The semiconductor integrated circuit according to claim 2, wherein the fuses and the page buffer are electrically connected by a bit line.

7. The semiconductor integrated circuit according to claim 1, wherein the fuses are spaced apart from one another by a minimum interval defined by a lithography process.

8. A semiconductor integrated circuit comprising:
a plurality of fuses each comprising a flash memory element that is programmed to be cut off by a first voltage; and
a page buffer electrically connected to the plurality of fuses and configured to determine the cut-off fuses.

9. The semiconductor integrated circuit according to claim 8, wherein each of the plurality of the fuses comprises:
a drain select transistor connected to a bit line and configured to be driven in response to a drain select signal;
a plurality of serially-connected flash memory elements electrically connected to the drain select transistor and configured to be driven in response to the first voltage applied through a word line; and
a source select transistor connected between the plurality of flash memory elements and a ground terminal and configured to be driven in response to a source select signal.

10. The semiconductor integrated circuit according to claim 9, wherein the first voltage is higher than a pumping voltage and lower than a programming voltage of the flash memory element.

11. The semiconductor integrated circuit according to claim 9, wherein the fuses and the page buffer are electrically connected by the bit line.

12. The semiconductor integrated circuit according to claim 8, is wherein the fuses are spaced apart from one another by a minimum interval defined by a lithography process.

13. A semiconductor integrated circuit comprising a flash memory cell that is used as a repair fuse.
